(19) United States
(12) Patent Application Publication
(10) Pub. No.: US 2026/0211835 A1
(43) Pub. Date: Jul. 23, 2026

(54) SERIALIZER AND A DESERIALIZER

(71) Applicant: SILICON MOTION, INC., Zhubei City (TW)

(72) Inventor: HAN-CHENG HUANG, Zhubei City (TW)

(21) Appl. No.: 19/198,143

(22) Filed: May 5, 2025

(30) Foreign Application Priority Data
Jan. 23, 2025 (TW) 114103189

(51) Int. Cl. G06F 13/42

(52) U.S. Cl. CPC G06F 13/4226

(57) ABSTRACT

The disclosure is related to a serializer and a deserializer. The serializer includes a serializing module and a data up-conversion processing module. The data up-conversion processing module receives a data packet sequence from a media access control block based on an output operating frequency and outputs the data packet sequence based on a serial operating frequency. The deserializer includes a deserializing module and a plurality of data down-conversion processing modules. The deserializer generates a data operating frequency based on a deserial operating frequency and outputs a restored data packet sequence based on the data operating frequency. The disclosure transmits or receives data in accordance with the operating frequency of the media access control block, and the data is exchanged at a transmission frequency that meets the transmission specification requirements of the physical layer. Thus, the convenience of using a serializer and a deserializer is improved.

### CROSS-REFERENCES

This application claims the priority benefit of Taiwan Patent Application Serial Number 114103189, filed on Jan. 23, 2025, the full disclosure of which is incorporated herein by reference.

### TECHNICAL FIELD

The present disclosure is related to the field of a serializer and a deserializer. More particularly, the embodiments are related to a serializer and a deserializer operating at a high frequency.

### DESCRIPTION OF RELATED ART

A serializer/deserializer (SerDes) is a physical (PHY) layer component that converts data between a parallel communication mode and a serial communication mode and allows large amounts of data to be transmitted at high speed between points using differential signals.

Generally, the serializer/deserializer directly connects to a media access control (MAC) layer device (e.g., a field programmable gate array (FPGA) chip). Since the operating frequency of the FPGA chip is relatively low (e.g., hundreds of MHz), the serializer/deserializer must operate at the lowest transmission frequency in accordance with the operating frequency of the FPGA chip.

However, as the transmission specifications of the physical layer are improved, the transmission frequency requirements for the serializer/deserializer are also increased accordingly. Therefore, existing devices and systems have considerable requirements for a serializer/deserializer that is applicable to MAC layer components and meets the transmission specification requirements of the physical layer.

### SUMMARY OF THE INVENTION

The embodiments of the present disclosure provide a serializer and a deserializer for transmitting and receiving data in accordance with the operating frequency of the FPGA chip and exchanging data according to a transmission frequency that meets the transmission specification requirements of the physical layer. Thus, the convenience of using a serializer and a deserializer is improved.

In order to achieve the above object and other related objects, the present disclosure provides a serializer for a physical layer interface of an electronic device. The serializer includes a serializing module and a data up-conversion processing module. The serializing module, having a serial operating frequency, is used for converting a data packet sequence transmitted in parallel to a dataflow transmitted in serial. The data up-conversion processing module includes a frequency division unit and a plurality of asynchrony register units. The frequency division unit is electrically connected to a media access control block and the serializing module. The frequency division unit is used for receiving the serial operating frequency and generating a device operating frequency based on the serial operating frequency. The device operating frequency is provided to the media access control block, and the device operating frequency is less than the serial operating frequency. Each of the asynchrony register units is electrically connected to the serializing module and the media access control block. The asynchrony register units are used for receiving the serial operating frequency and an output operating frequency from the media access control block. The asynchrony register units receive the data packet sequence from the media access control block based on the output operating frequency and output the data packet sequence based on the serial operating frequency. The output operating frequency is less than the serial operating frequency. The data packet sequence includes a plurality of non-repeated data packets, and the dataflow includes repeated data packets.

In order to achieve the above object and other related objects, the present disclosure provides a deserializer for a physical layer interface of an electronic device. The deserializer includes a deserializing module and a plurality of data down-conversion processing modules. The deserializing module, having a deserial operating frequency, is used for receiving a dataflow transmitted in serial and converting the dataflow to a data packet sequence transmitted in parallel. The data packet sequence includes repeated data packets. Each of the data down-conversion processing modules includes a frequency division unit, an alignment unit and a packet discard unit. The frequency division unit is electrically connected to a media access control block and the deserializing module. The frequency division unit is used for receiving the deserial operating frequency and generating a data operating frequency based on the deserial operating frequency. The data operating frequency is provided to the media access control block. The data operating frequency is less than the deserial operating frequency. The alignment unit is electrically connected to the deserializing module. The alignment unit is used for receiving the deserial operating frequency and the data packet sequence from the deserializing module and determining a starting position of each data packet in the data packet sequence. The packet discard unit is electrically connected to the alignment unit and the deserializing module. The packet discard unit is used for receiving the deserial operating frequency and the data packet sequence from the alignment unit, discarding the repeated data packets in the data packet sequence, and outputting a restored data packet sequence comprising non-repeated data packets.

According to the above, data transmitted at a low transition frequency can be upconverted to data transmitted at a high transition frequency through the data up-conversion processing module of the serializer of the present disclosure, and the received data transmitted at a high transition frequency can be down-converted to data transmitted at a low transition frequency through the deserializer of the present disclosure. The serializer and the deserializer can transmit and receive data transmitted at a low transition frequency in accordance with the operating frequency of the MAC layer components and exchange data according to a transmission frequency that meets the transmission specification requirements of the physical layer. Therefore, the convenience of using a serializer and a deserializer is improved.

### BRIEF DESCRIPTION OF DRAWINGS

FIG. 1 is a schematic of a block of an electronic device.

FIG. 2 is an application schematic of an electronic device.

FIG. 3 is a schematic of a serializer according to an embodiment of the present disclosure.

FIG. 4 is a schematic of a data packet sequence according to an embodiment of the present disclosure.

FIG. 5 is a schematic of a deserializer according to an embodiment of the present disclosure.

FIG. 6 is a schematic of a data packet sequence according to an embodiment of the present disclosure.

### DESCRIPTION OF THE INVENTION

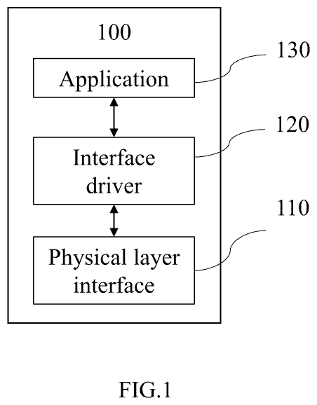

Please refer to FIG. 1. FIG. 1 is a schematic of a block of an electronic device 100. The electronic device 100 is a portable electronic device (for example, a smartphone, a tablet computer, etc.) or a non-portable electronic device (for example, a desktop computer). The electronic device 100 is a data storage device or a flash storage device. For example, the electronic device 100 is a solid-state disk (SSD) or a flash memory. Generally, the electronic device 100 includes a physical layer interface 110, an interface driver 120, and an application 130. The physical layer interface 110 is a physical circuit interface for providing signals (data) to external devices and receiving signals from external devices. The physical layer interface 110 is, for example, a physical circuit that complies with the MIPI M-PHY™ physical layer specification. The physical layer interface 110 is, for example, a physical circuit that complies with the PCIe (Peripheral Component Interconnect Express) standard. The physical layer interface 110 is, for example, a physical circuit interface suitable for Universal Flash Storage (UFS). The interface driver 120 is electrically connected to the physical layer interface 110. The interface driver 120 is used to generate or decode the data packets to execute a task designated by the application 130. When the application is from a memory system, the task is, for example, a reading operation or a writing operation. The data packets generated by the interface driver 120 are provided to the physical layer interface 110 for being transmitted through the physical layer interface 110. The interface driver 120 is, for example, a UFS driver. The application 130 is executed by the electronic device 100. For example, an application for a reading operation of a memory system is executed under the control of a user. Therefore, based on the control of the user, the electronic device 100 may implement the data packet transmission required by the application 130 through the physical layer interface 110 and the interface driver 120.

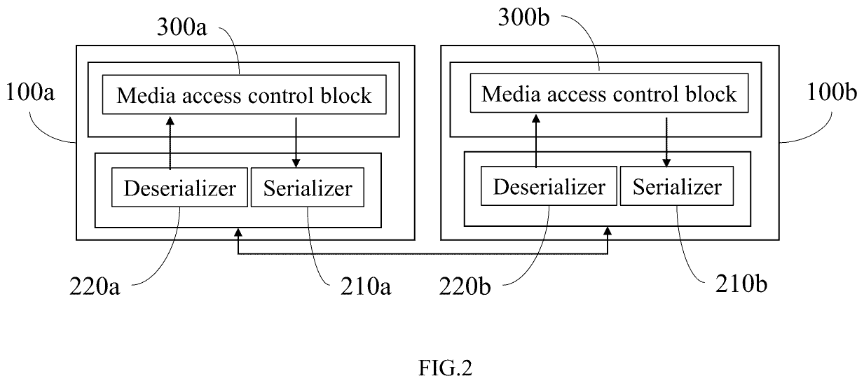

Please refer to FIG. 1 and FIG. 2. FIG. 2 is an application schematic of an electronic device. FIG. 2 includes an electronic device 100a and an electronic device 100b. The electronic device 100a is, for example, a host computer device. The electronic device 100b is, for example, a flash storage device, but the present disclosure is not limited thereto. The electronic device 100a includes a serializer 210a and a deserializer 220a for implementing physical layer functions and a media access control block 300a for implementing media access control layer functions. The serializer 210a and the deserializer 220a are for example the physical layer interface 110 mentioned above. The media access control block 300a is for example the interface driver 120 mentioned above. The electronic device 100b includes a serializer 210b and a deserializer 220b for implementing physical layer functions and a media access control block 300b for implementing media access control layer functions. The serializer 210b and the deserializer 220b are for example the physical layer interface 110 mentioned above. The media access control block 300b is for example the interface driver 120 mentioned above. The electrical connection between the electronic device 100a and the electronic device 100b is established through the serializers 210a, 210b and the deserializers 220a, 220b.

The media access control block 300a is electrically connected to the serializer 210a and the deserializer 220a. The media access control block 300a is used to generate a data packet sequence transmitted in parallel and transmit the data packet sequence to the serializer 210a. The media access control block 300a is used to receive a data packet sequence from the deserializer 220a. The serializer 210a is used to receive the data packet sequence from the media access control block 300a, convert the data packet sequence transmitted in parallel to a data flow transmitted in serial, and transmit the data flow to the deserializer 220b of the electronic device 100b. The deserializer 220a is used to receive a data flow from the serializer 210b of the electronic device 100b, convert the data flow transmitted in serial to a data packet sequence transmitted in parallel, and transmit the data packet sequence to the media access control block 300a of the electronic device 100a. The operations of the media access control block 300b, the serializer 210b and the deserializer 220b are same as the operations of the media access control block 300a, the serializer 210a and the deserializer 220a and thus are not described again herein.

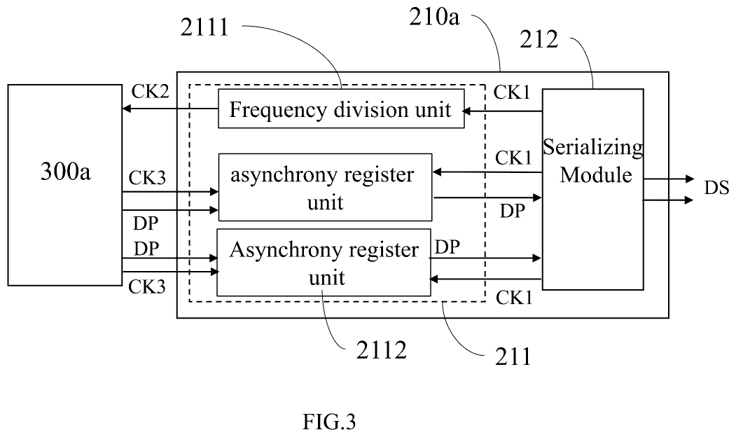

Please refer to FIG. 3. FIG. 3 is a schematic of a serializer according to an embodiment of the present disclosure. In FIG. 3, the serializer 210a is employed as an example for explanation. The serializer 210a is electrically connected to the media access control block 300a. The serializer 210a is used to provide a device operating frequency CK2 to the media access control block 300a. The device operating frequency CK2 is less than a serial operating frequency CK1. The device operating frequency CK2 is the frequency at which the media access control block 300a can operate. The media access control block 300a generates the data packet sequence DP transmitted in parallel based on the received device operating frequency CK2, and the device operating frequency CK2 is provided as an output operating frequency CK3 to the serializer 210a by the media access control block 300a. Therefore, based on the received device operating frequency CK2, the media access control block 300a may generate the data packet sequence DP transmitted in parallel with the output operating frequency CK3 corresponding to the device operating frequency CK2.

The serializer 210a includes a data up-conversion processing module 211 and a serializing module 212. The serializing module 212 is electrically connected to the data up-conversion processing module 211. The serializing module 212 has the serial operating frequency CK1 and receives the data packet sequence DP transmitted in parallel from the data up-conversion processing module 211. The serializing module 212 is used to operate at the serial operating frequency CK1 and convert the received data packet sequence DP transmitted in parallel to a dataflow DS transmitted in serial based on the serial operating frequency CK1. The data up-conversion processing module 211 includes a frequency division unit 2111 and a plurality of asynchrony register units 2112. The frequency division unit 2111 is electrically connected to the media access control block 300a and the serializing module 212. The frequency division unit 2111 is used to receive the serial operating frequency CK1 of the serializing module 212 and generate the device operating frequency CK2 based on the serial operating frequency CK1. The frequency division unit 2111 is used to down-convert the serial operating frequency CK1 to the device operating frequency CK2 with a lower frequency based on a frequency division multiple (such as two, four or six). The asynchrony register unit 2112 is electrically connected to the media access control block 300a and the serializing module 212. The asynchrony register unit 2112 receives the serial operating frequency CK1 and the output operating frequency CK3 from the media access control block 300a. The asynchrony register unit 2112 receives the data packet sequence DP from the media access control block 300a based on the output operating frequency CK3 and outputs the data packet sequence DP based on the serial operating frequency CK1. The asynchrony register unit 2112 is, for example, an asynchronous fifo. The number of the asynchrony register units 2112 is related to the frequency division multiple of the frequency division unit 2111. For example, when the frequency division multiple of the frequency division unit 2111 is two, the number of asynchronous register units 2112 corresponds to the frequency division multiple, which is two. Therefore, the data packet sequence DP transmitted at the output operating frequency CK3 may be converted and transmitted at the serial operating frequency CK1. The serializing module 212 therefore may operate at the serial operating frequency CK1, which is a higher frequency.

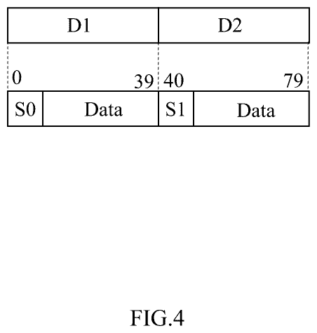

Please refer to FIG. 4. FIG. 4 is a schematic of a data packet sequence according to an embodiment of the present disclosure. The data packet sequence DP includes a plurality of data packets D1, D2. Each of the data packets D1 or D2 includes a plurality of sync bits and a plurality of data bits. As shown in the data packet D1, the data packet D1 includes a plurality of sync bits S0 and a plurality of data bits Data. Different data packets have different sync bits. For example, the sync bits S0 of the data packet D1 are different to the sync bits S1 of the data packet D2.

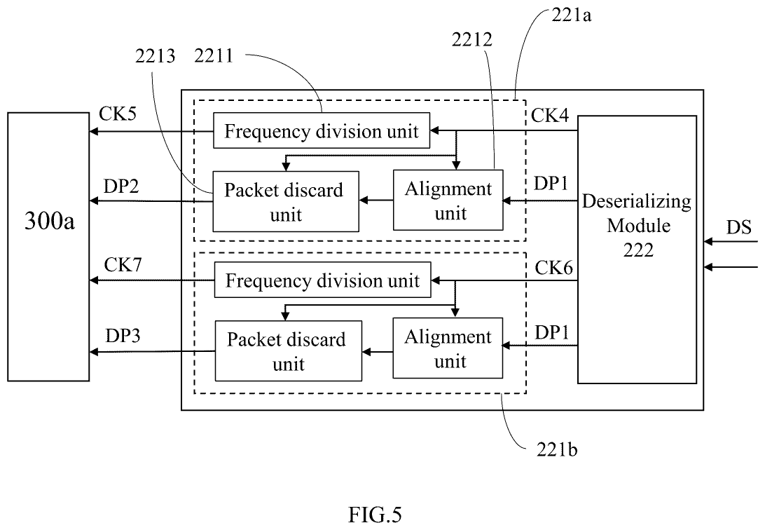

Please refer to FIG. 5. FIG. 5 is a schematic of a deserializer according to an embodiment of the present disclosure. In FIG. 5, the deserializer 220a is employed as an example for explanation. The deserializer 220a is electrically connected to the media access control block 300a. The deserializer 220a is used to provide a plurality of data operating frequencies (such as the data operating frequencies CK5 and CK7) and corresponding restored data packet sequences DP2, DP3 to the media access control block 300a. The data operating frequencies CK5 and CK7 are the frequencies at which the media access control block 300a can operate. The media access control block 300a may read the data packet sequences DP2, DP3 based on the received data operating frequencies CK5, CK7.

The deserializer 220a includes a deserializing module 222 and a plurality of data down-conversion processing modules 221a, 221b. The number of the data down-conversion processing modules 221a, 221b corresponds to the frequency division multiple. The deserializing module 222 has a deserial operating frequency. The deserializing module 222 receives the dataflow DS from the serializer 210b based on the deserial operating frequency and converts the dataflow DS to a data packet sequence DP1. The deserializing module 222 further generates the data operating frequencies CK4, CK6. The data operating frequency CK4 is different to the data operating frequency CK6.

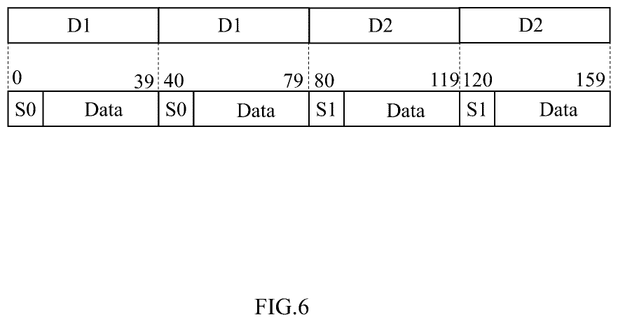

Please refer to FIG. 6. FIG. 6 is a schematic of a data packet sequence DP1 according to an embodiment of the present disclosure. The data packet sequence DP1 includes repeated data packets D1, D2. For example, the data packet sequence DP1 includes two data packets D1 and two data packets D2. The number of repeated data packets of the data packet D1 and the data packet D2 is related to the frequency division multiple of the frequency division unit 2111 and/or a frequency division unit 2211 of the data down-conversion processing module 221a or 221b. For example, the frequency division multiple is two, and the data packet sequence DP1 corresponds to the frequency division multiple, therefore including two data packets D1.

Each of the data down-conversion processing modules 221a, 221b includes a frequency division unit 2211, an alignment unit 2212 and a packet discard unit 2213. The data down-conversion processing module 221a is employed as an example for explanation. The frequency division unit 2211 is electrically connected to the media access control block 300a and the deserializing module 222. The frequency division unit 2211 is used to receive the data processing frequency CK4 and generate the data operating frequency CK5 based on the data processing frequency CK4 and the frequency division multiple. The data operating frequency CK5 is provided to the media access control block 300a, and the data operating frequency CK5 is less than the data processing frequency CK4 and the deserial operating frequency. The frequency division multiple of the frequency division unit 2211 is the same as the frequency division multiple of the frequency division unit 2111. The alignment unit 2212 is electrically connected to the deserializing module 222. The alignment unit 2212 is used to receive the data processing frequency CK4 and the data packet sequence DP1 from the deserializing module 222. The alignment unit 2212 is used to determine a starting position of each of the data packets in the data packet sequence DP1. The alignment unit 2212 is used to recognize the sync bits of each of the data packets for determining the starting positions of each of the data packets in the data packet sequence. For example, based on the data processing frequency CK4, the alignment unit 2212 recognizes the sync bit S0 of the data packet D1 and determines the starting position of the data packet D1. The starting position is, for example, the position of bit 0 in FIG. 6. In an embodiment, the alignment unit 2212 may be implemented by a logic circuit. The packet discard unit 2213 is electrically connected to the alignment unit 2212, the deserializing module 222 and the media access control block 300a. The packet discard unit 2213 receives the data processing frequency CK4, the data packet sequence DP1 from the alignment unit 2212 and the starting position of the data packet D1. The packet discard unit 2213 reads the data packet sequence DP1 based on the data processing frequency CK4 and determines the position of the first data packet D1 in the data packet sequence DP1 based on the starting position of the data packet D1. The packet discard unit 2213 further discards the repeated data packet D1 in the data packet sequence DP1 and outputs a restored data packet sequence DP2 to the media access control block 300a. The restored data packet sequence DP2 includes non-repeated data packet D1. Please refer to FIG. 6. The packet discard unit 2213 may read the data from bit 0 to bit 39 based on the starting position of the data packet D1 and the known size of the data packet D1 and output the data from bit 0 to bit 39 as the data packet D1. The packet discard unit 2213 further does not read the data from bit 40 to bit 79 for discarding the repeated data packet D1. The data down-conversion processing module 221b is used to receive the data processing frequency CK6, generate the data operating frequency CK7, and output a restored data packet sequence DP3 to the media access control block 300a. The restored data packet sequence DP3 includes a non-repeated data packet D2. The operations of the data down-conversion processing module 221b are the same as those of the data down-conversion processing module 221a and thus are not described again herein.

According to the above, the serializer of the present disclosure may up-convert received data transmitted at a low frequency to data transmitted at a high frequency through the data up-conversion processing module, and the deserializer may down-convert received data transmitted at a high frequency to data transmitted at a low frequency. Thus, the serializer and the deserializer of the present disclosure may match the operating frequency of the media access control layer device to transmit or receive data with a low transmission frequency and exchange data at a transmission frequency that complies with the transmission specification requirements of the physical layer. The convenience of using a serializer and a deserializer is thus improved.

1. A serializer for a physical layer interface of an electronic device, comprising:
a serializing module, having a serial operating frequency, for converting a data packet sequence transmitted in parallel to a dataflow transmitted in serial; and
a data up-conversion processing module, comprising:
a frequency division unit, electrically connected to a media access control block and the serializing module, for receiving the serial operating frequency and generating a device operating frequency based on the serial operating frequency, wherein the device operating frequency is provided to the media access control block, and the device operating frequency is less than the serial operating frequency; and
a plurality of asynchrony register units, electrically connected to the media access control block and the serializing module, wherein each of the asynchrony register units receives the serial operating frequency and an output operating frequency from the media access control block for receiving the data packet sequence from the media access control block based on the output operating frequency and for outputting the data packet sequence based on the serial operating frequency, and the output operating frequency is less than the serial operating frequency;
wherein the data packet sequence comprises a plurality of non-repeated data packets, and the dataflow comprises repeated data packets.

2. The serializer claimed in claim 1, wherein a number of the asynchrony register units and a number of the repeated data packets are related to a frequency division multiple of the frequency division unit.

3. The serializer claimed in claim 1, wherein each of the data packets comprises a plurality of sync bits and a plurality of data bits, and the different data packets have different sync bits.

4. The serializer claimed in claim 1, wherein each of the asynchrony register units is an asynchronous fifo.

5. The serializer claimed in claim 1, wherein the output operating frequency is the same as the device operating frequency.

6. A deserializer for a physical layer interface of an electronic device, comprising:
a deserializing module, having a deserial operating frequency, for receiving a dataflow transmitted in serial and converting the dataflow to a data packet sequence transmitted in parallel, wherein the data packet sequence comprises repeated data packets; and
a plurality of data down-conversion processing modules, each of the data down-conversion processing modules comprising:
a frequency division unit, electrically connected to a media access control block and the deserializing module, for receiving a data processing frequency and generating a data operating frequency based on the data processing frequency, wherein the data operating frequency is provided to the media access control block and the data operating frequency is less than the deserial operating frequency;
an alignment unit, electrically connected to the deserializing module, for receiving the data processing frequency and the data packet sequence from the deserializing module, and for determining a starting position of each data packet in the data packet sequence; and
a packet discard unit, electrically connected to the alignment unit and the deserializing module, for receiving the data processing frequency and the data packet sequence from the alignment unit, discarding the repeated data packets in the data packet sequence, and outputting a restored data packet sequence comprising non-repeated data packets.

7. The deserializer claimed in claim 6, wherein a number of the data down-conversion processing modules and a number of repeated data packets are related to a frequency division multiple of the frequency division unit.

8. The deserializer claimed in claim 6, wherein the data processing frequencies of each of the data down-conversion processing modules are different.

9. The deserializer claimed in claim 6, wherein each of the data packets comprises a plurality of sync bits and a plurality of data bits, and the different data packets have different sync bits.

10. The deserializer claimed in claim 9, wherein the alignment unit is configured to identify the sync bits for determining the starting positions of each of the data packets in the data packet sequence based on the sync bits.
